(19) United States
(12) Patent Application Publication
(10) Pub. No.: US 2020/0075090 A1
(43) Pub. Date: Mar. 5, 2020

(54) PULSED APPLICATION OF WORDLINE UNDERDRIVE (WLUD) FOR ENHANCING STABILITY OF STATIC RANDOM ACCESS MEMORY (SRAM) OPERATION IN A LOW SUPPLY VOLTAGE ENVIRONMENT

(71) Applicant: STMicroelectronics International N.V., Plan-les-Ouates (CH)

(72) Inventors: Ashish KUMAR, Ranchi (IN); Mohammad Aftab ALAM, Masaurhi (IN)

(73) Assignee: STMicroelectronics International N.V., Plan-les-Ouates (CH)

(21) Appl. No.: 16/542,432

(22) Filed: Aug. 16, 2019

Related U.S. Application Data
(60) Provisional application No. 62/726,502, filed on Sep. 4, 2018.

(51) Int. Cl. G11C 11/418; G11C 8/08; G11C 11/419

(52) U.S. Cl. CPC G11C 11/418; G11C 11/419; G11C 8/08

(57) ABSTRACT

A wordline coupled to a memory cell is selected in connection with performing a read/write operation at the memory cell. A wordline signal is asserted on the selected wordline. The assertion of the wordline signal has a leading edge and a trailing edge and, between the leading edge and trailing edge, a series of wordline underdrive pulses. Each wordline underdrive pulse causes a wordline voltage to fall from a first voltage level to a second voltage level and then rise from the second voltage level to the first voltage level. The first and second voltage levels are both greater than a ground voltage of the memory cell.

### RELATED APPLICATION

This application claims priority to United States Provisional Application for Patent No. 62/726,502, filed Sep. 4, 2018, the contents of which are incorporated by reference to the maximum extent allowable under the law.

### TECHNICAL FIELD

This disclosure relates to integrated memory circuits and, in particular, to a wordline underdrive assist circuit for a static random access memory (SRAM).

### BACKGROUND

Reference is made to FIG. 1 which shows a schematic diagram of a standard memory circuit 10 including a plurality of memory cells 12 that are typically arranged in an array including plural columns and rows. Each memory cell 12 in this implementation is, for example, a conventional six transistor (6T) static random access memory (SRAM) cell 12. The memory circuit 10 further includes a wordline driver 14 for each row and an address decoder 16 configured to control operation of the wordline drivers.

Each memory cell 12 includes two cross-coupled CMOS inverters 22 and 24, each inverter including a series connected p-channel and n-channel MOSFET transistor pair. The inputs and outputs of the inverters 22 and 24 are coupled to form a latch circuit having a true data storage node QT and a complement data storage node QB. The cell 12 further includes two transfer (passgate) transistors 26 and 28 whose gate terminals are driven by a wordline (WL) that is coupled to an output of the wordline driver 14. Transistor 26 is source-drain connected between the true data storage node QT and a node associated with a true bitline (BLT). Transistor 28 is source-drain connected between the complement data storage node QB and a node associated with a complement bitline (BLB). The source terminals of the p-channel transistors 30 and 32 in each inverter 22 and 24 are coupled to receive a high supply voltage (for example, Vdd) at a high supply node, while the source terminals of the n-channel transistors 34 and 36 in each inverter 22 and 24 are coupled to receive a low supply voltage (for example, Gnd) at a low supply node. The high supply voltage Vdd at the high supply node and the low supply voltage Gnd at the low supply node comprise the power supply set of voltages for the cell 12.

The wordline driver circuit 14 includes a series connected p-channel and n-channel MOSFET transistor pair forming a logic inverter. The wordline driver circuit 14 is also coupled to receive the high supply voltage (Vdd) at the high supply node and is referenced to the low supply voltage (Gnd) at the low supply node. The input of the wordline driver circuit 14 is coupled to an output of the address decoder 16 and the wordline (WL) for a row of cells 12 is coupled to the output of the corresponding wordline driver circuit 14. The address decoder 16 receives an address (Addr), decodes the received address and selectively actuates the wordline through the wordline driver circuit 14 to assert a logic high wordline signal.

The SRAM cell 12 is a preferred memory element in many applications, including system on chip (SoC) applications, because of its small size and fast data access operation. The memory circuit 10 will include many SRAM cells 12, and thus the size of each SRAM cell is an important design consideration. Effort is made to use the smallest possible transistor devices for the SRAM cell 12 in order to reduce die area and control cost. However, the use of small transistor devices increases concerns with variation and stability.

It is also of importance to operate the memory circuit 10 at a lowest possible level of the high supply voltage (Vdd). Static noise margin (SNM) is a measure of stability of the SRAM cell 12 during access, and write margin (WM) is a measure of ease of writing data into the cell. Both SNM and WM are reduced with decrease in the high supply voltage Vdd level, and hence there is a corresponding decrease in stability as supply voltage is reduced. Indeed, it is known to those skilled in the art that the SRAM cell 12 becomes unstable due to low SNM at lower supply voltages because the data stored in the cell can flip upon access.

A number of techniques have been developed to assist operation of the SRAM cell 12 when a reduced supply voltage Vdd level is used. One technique is referred to as wordline underdrive (WLUD) where the logic high voltage on the wordline is pulled down by a wordline underdrive assist circuit 40 to a voltage lower than supply voltage in order to provide sufficient static noise margin (SNM) for the read and write operation. When wordline underdrive is active, the logic high voltage level of the wordline signal applied to the gates of the transfer (passgate) transistors 26 and 28 is less than the supply voltage Vdd level. The wordline WL is essentially underdriven by a ΔV voltage such that the logic high voltage level of the asserted wordline signal is at a voltage level of Vdd-AV. The effect of the wordline underdrive technique is to reduce the strength of the transfer (passgate) transistors 26 and 28. FIG. 2 shows a comparison of a wordline signal voltage for a first case 42 that does not utilize the wordline underdrive technique and a second case 44 that does utilize the wordline underdrive technique.

A drawback of the use of the wordline underdrive technique is a decrease in cell current and a corresponding decrease in operational frequency. The application of the reduced wordline voltage increases the flipping time of the cell as shown in FIG. 3 where the first case 42 has a flipping time Tflip and the second case has a flipping time Tflip+ΔT.

### SUMMARY

In an embodiment, a method comprises: decoding an address to select a wordline coupled to a memory cell; asserting a wordline signal on the selected wordline to perform a read/write operation at the memory cell, the asserted wordline signal having a leading edge and a trailing edge; and between the leading edge and trailing edge, applying a plurality of wordline underdrive pulses to the asserted wordline signal, each wordline underdrive pulse causing a voltage of the asserted wordline signal to fall from a first voltage level to a second voltage level and then rise from the second voltage level to the first voltage level; wherein the first and second voltage levels are both greater than a ground voltage of the memory cell.

In an embodiment, a method comprises: selecting a wordline coupled to a memory cell; and making a single assertion of a wordline signal on the selected wordline to perform a read/write operation at the memory cell, wherein the single assertion has a leading edge and a trailing edge and, between the leading edge and trailing edge, the single assertion further includes a plurality of wordline underdrive pulses wherein each wordline underdrive pulse causes a wordline voltage to fall from a first voltage level to a second voltage level and then rise from the second voltage level to the first voltage level; wherein the first and second voltage levels are both greater than a ground voltage of the memory cell.

In an embodiment, a circuit comprises: a wordline configured to be coupled to a memory cell powered by a supply voltage; a pull-up transistor having a source-drain path connected between the supply voltage and the wordline wherein the pull-up transistor is actuated in response to selection of the wordline to perform a read/write operation at the memory cell; a pull-down transistor having a source-drain path connected between the wordline and a ground node; and a control circuit configured to apply a control signal to a control terminal of the pull-down transistor to provide wordline underdrive which includes a plurality of wordline underdrive pulses; wherein each wordline underdrive pulse causes a wordline voltage to fall from a first voltage level to a second voltage level and then rise from the second voltage level to the first voltage level; and wherein the first and second voltage levels are both greater than a ground voltage of the memory cell.

### BRIEF DESCRIPTION OF THE DRAWINGS

For a better understanding of the invention, reference will now be made by way of example only to the accompanying figures in which:

FIG. 1 is a schematic diagram of a standard memory circuit with wordline underdrive (WLUD) assist;

FIG. 2 is a timing diagram showing a comparison of the wordline voltages when using and not using wordline underdrive;

FIG. 3 is a timing diagram showing a comparison of the timing for cell flip when using and not using wordline underdrive;

FIG. 4 is a schematic diagram of a memory circuit with pulsed wordline underdrive (WLUD) assist;

FIG. 5 is a timing diagram showing an embodiment of pulsed wordline underdrive;

FIG. 6 is a timing diagram showing another embodiment of pulsed wordline underdrive;

FIGS. 7A-7B are block diagrams of the pulsed wordline underdrive assist circuit; and

FIG. 8 illustrates a comparison of operation using a conventional wordline underdrive (as with FIG. 1) and the pulsed wordline underdrive (as with FIG. 4).

### DETAILED DESCRIPTION OF THE DRAWINGS

Reference is made to FIG. 4 which shows a schematic diagram of a memory circuit 110 including a plurality of memory cells 12 that are typically arranged in an array including plural columns and rows. Each memory cell 12 in this implementation is, for example, a conventional six transistor (6T) static random access memory (SRAM) cell 12. The memory circuit 110 further includes a wordline driver 14 for each row and an address decoder 16 configured to control operation of the wordline drivers.

Each memory cell 12 includes two cross-coupled CMOS inverters 22 and 24, each inverter including a series connected p-channel and n-channel MOSFET transistor pair. The inputs and outputs of the inverters 22 and 24 are coupled to form a latch circuit having a true data storage node QT and a complement data storage node QB. The cell 12 further includes two transfer (passgate) transistors 26 and 28 whose gate terminals are driven by a wordline (WL) that is coupled to an output of the wordline driver 14. Transistor 26 is source-drain connected between the true data storage node QT and a node associated with a true bitline (BLT). Transistor 28 is source-drain connected between the complement data storage node QB and a node associated with a complement bitline (BLB). The source terminals of the p-channel transistors 30 and 32 in each inverter 22 and 24 are coupled to receive a high supply voltage (for example, Vdd) at a high supply node, while the source terminals of the n-channel transistors 34 and 36 in each inverter 22 and 24 are coupled to receive a low supply voltage (for example, Gnd) at a low supply node. The high supply voltage Vdd at the high supply node and the low supply voltage Gnd at the low supply node comprise the power supply set of voltages for the cell 12.

The wordline driver circuit 14 includes a series connected p-channel and n-channel MOSFET transistor pair forming a logic inverter. The wordline driver circuit 14 is also coupled to receive the high supply voltage (Vdd) at the high supply node and is referenced to the low supply voltage (Gnd) at the low supply node. The input of the wordline driver circuit 14 is coupled to an output of the address decoder 16 and the wordline (WL) for a row of cells 12 is coupled to the output of the corresponding wordline driver circuit 14. The address decoder 16 receives an address (Addr), decodes the received address and selectively actuates the wordline through the wordline driver circuit 14 to assert a logic high wordline signal.

The memory circuit 110 supports an improved form of wordline underdrive (WLUD) using a pulsed wordline underdrive assist circuit 140. The pulsed wordline underdrive assist circuit 140 is coupled to the wordlines WL and may be selectively actuated by the address decoder 16.

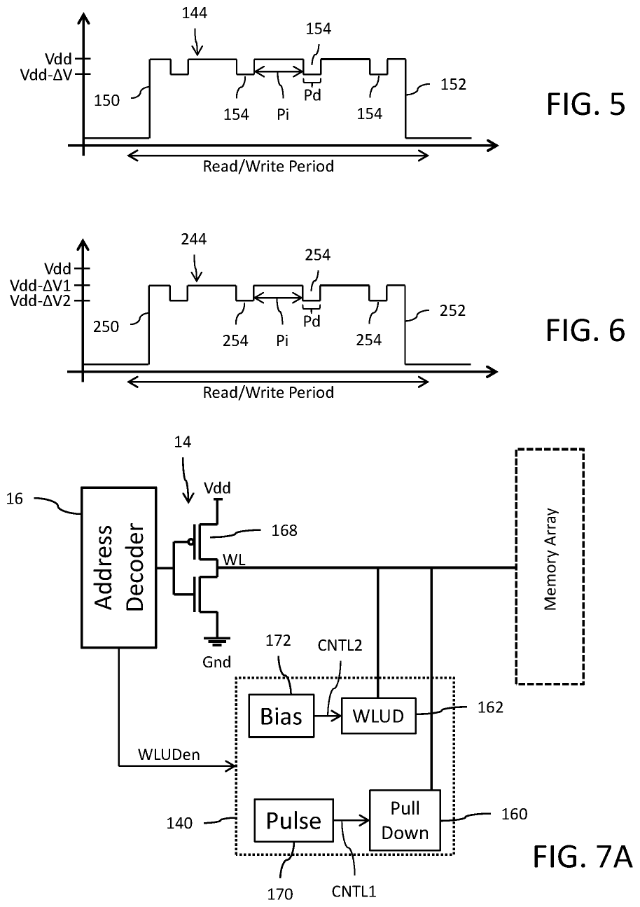

FIG. 5 shows a timing diagram for a single assertion 144 of the wordline (responsive to an address decode which selects the wordline) to logic high in accordance with one embodiment of the pulsed wordline underdrive technique. The assertion 144 of the wordline by the address decoder 16 through the wordline driver circuit 14 corresponds to a read or write period and includes a leading edge 150 where the voltage of the wordline signal rises from the low supply voltage (Gnd) to the high supply voltage (Vdd) and a trailing edge 152 where the voltage of the wordline signal falls from the high supply voltage (Vdd) to the low supply voltage (Gnd). In between the leading edge 150 and the trailing edge 152 of the asserted wordline signal, the pulsed wordline underdrive assist circuit 140 applies a plurality of underdrive pulses 154 to the wordline which cause the logic high voltage of the wordline signal to fall by ΔV (where ΔV<Vdd). The value of the ΔV voltage, the duration (Pd) of each underdrive pulse 154 and the value of the interval (Pi) between successive underdrive pulses 154 is configurable by the pulsed wordline underdrive assist circuit 140.

FIG. 6 shows a timing diagram for a single assertion 244 of the wordline (responsive to an address decode which selects the wordline) in accordance with another embodiment of the pulsed wordline underdrive technique. The assertion 244 of the wordline by the address decoder 16 through the wordline driver circuit 14 corresponds to a read or write period and includes a leading edge 250 where the voltage of the wordline signal rises from the low supply voltage (Gnd) to a fixed underdrive voltage (Vdd−ΔV1; where ΔV1<Vdd) and a trailing edge 252 where the voltage of the wordline signal falls from the fixed underdrive voltage (Vdd−ΔV1) to the low supply voltage (Gnd). In between the leading edge 250 and the trailing edge 252 of the asserted wordline signal, the pulsed wordline underdrive assist circuit 140 applies a plurality of underdrive pulses 254 to the wordline which cause the logic high voltage of the wordline signal to fall by ΔV2 (where ΔV2<Vdd; and ΔV1+ΔV2<Vdd). The values of the ΔV1 and ΔV2 voltages, the duration (Pd) of each underdrive pulse 254 and the value of the interval (Pi) between successive underdrive pulses 254 is configurable by the pulsed wordline underdrive assist circuit 140.

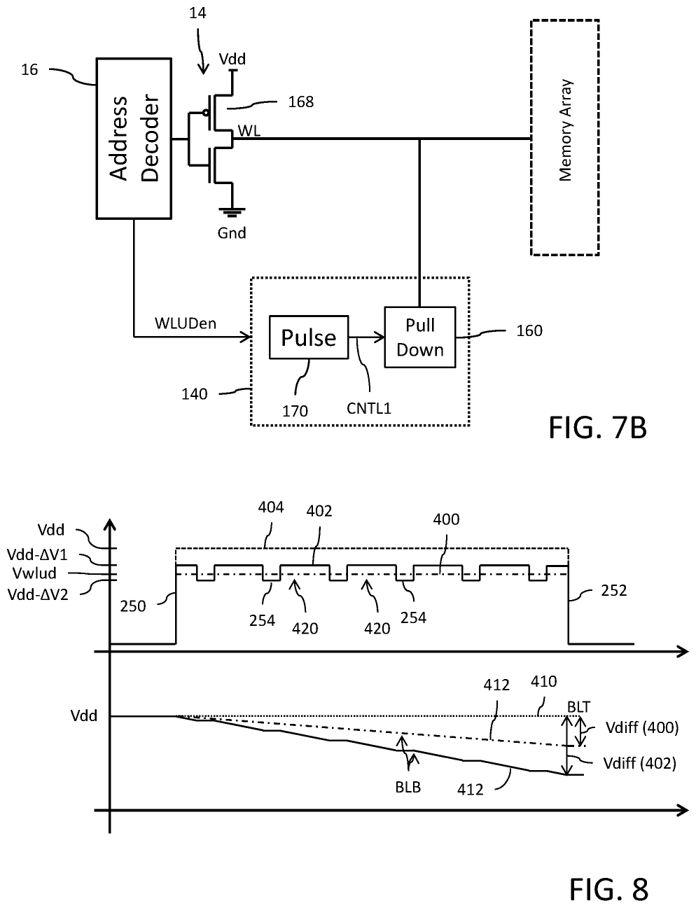

Reference is now made to FIG. 7A which shows a block diagram of the pulsed wordline underdrive assist circuit 140. A pull-down circuit 160 is coupled between the wordline WL and the low supply voltage (Gnd) node. The conductivity of the pull-down circuit 160 is controlled by a first control signal CNTL1. The first control signal CNTL1 is modulated by a pulse circuit 170. The pulse circuit 170 can apply pulses to the pull-down circuit 160 for selecting the voltage level ΔV or ΔV2 of the pulses for the pulsed wordline underdrive assist. A wordline underdrive circuit 162 is coupled between the wordline WL and the low supply voltage (Gnd) node. The conductivity of the wordline underdrive circuit 162 is controlled by a second control signal CNTL2. The second control signal CNTL2 is modulated by a bias circuit 172. The bias circuit 172 can apply a bias to the pull-down circuit 160 for selecting the voltage level ΔV1 for the fixed underdrive voltage. The pulsed wordline underdrive assist circuit 140 is enabled for operation by a wordline underdrive enable signal (WLUDen) generated by the address decoder. The pulse circuit 170 is configurable to select the values of the ΔV or ΔV2 voltages, the duration (Pd) and the value of the interval (Pi). The bias circuit 172 is configurable to select the magnitude of the voltage level ΔV1.

In an embodiment, the pull-down circuit 160 may comprise an n-channel pull-down transistor that is source-drain coupled between the wordline WL and the low supply voltage (Gnd) node. The first control signal CNTL1 is applied to the gate of the pull-down transistor. The pull-down transistor of the pull-down circuit 160 and the p-channel pull-up transistor 168 of the driver 12 form a voltage divider circuit when both transistors are active and this voltage division sets the voltage level at the wordline for implementing the pulses for the pulsed wordline underdrive assist.

In an embodiment, the wordline underdrive circuit 162 may comprise an n-channel pull-down transistor that is source-drain coupled between the wordline WL and the low supply voltage (Gnd) node. The second control signal CNTL2 is applied to the gate of the pull-down transistor. The pull-down transistor of the pull-down circuit 162 and the p-channel pull-up transistor 168 of the driver 12 form a voltage divider circuit when both transistors are active and this voltage division sets the voltage level at the wordline for implementing the wordline underdrive.

It will be understood that the wordline underdrive circuit 162 may be omitted, or alternatively selectively disabled, so that the pulsed wordline underdrive assist applies only the pulses. An example of such an implementation is shown in FIG. 7B.

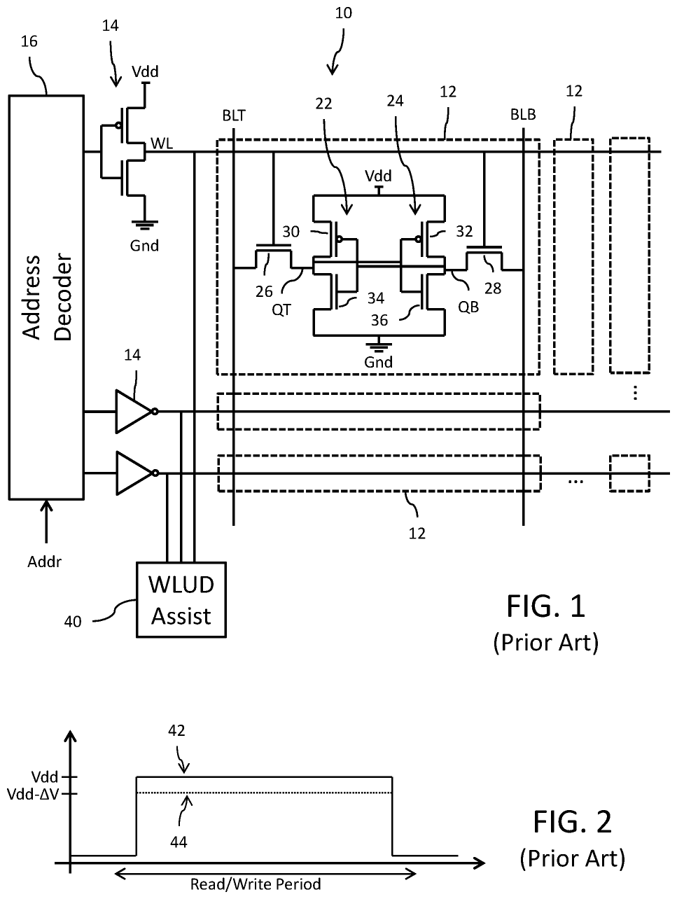

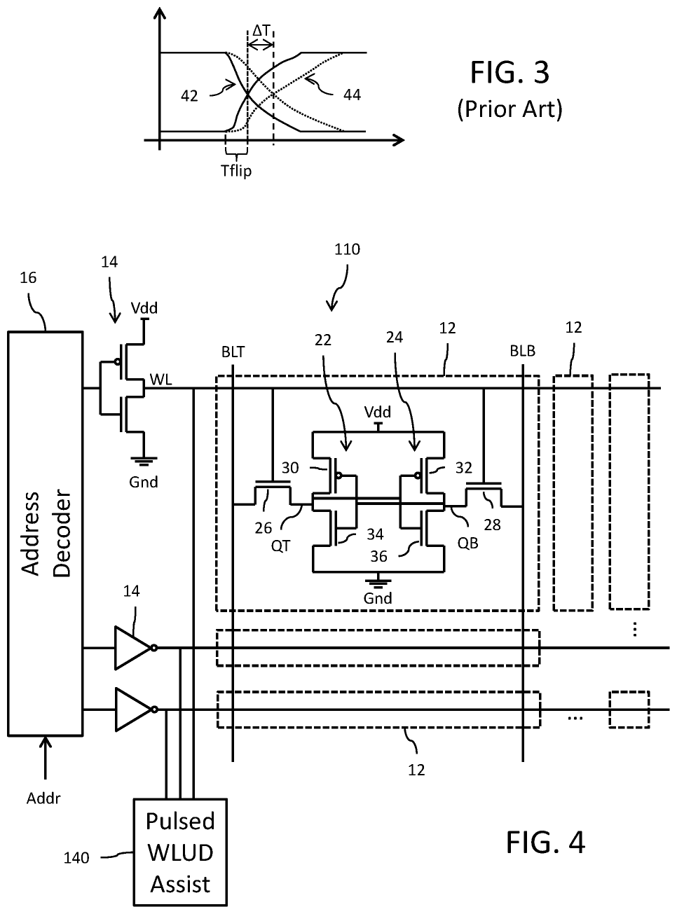

Reference is now made to FIG. 8 which illustrates a comparison of operation using a conventional wordline underdrive (as with FIG. 1) and the pulsed wordline underdrive (as with FIG. 4). The top part of FIG. 8 shows the assertion of the wordline signal with the conventional wordline underdrive (reference 400), the assertion of the wordline signal with the pulsed wordline underdrive (reference 402) and the assertion of the wordline without any form of wordline underdrive (reference 404). In each case, the assertion of the wordline signal has a leading edge 250 and a trailing edge 252. Between the edges 250 and 252, the wordline signal without any form of wordline underdrive (reference 404) is at a voltage level of Vdd. Between the edges 250 and 252, the wordline signal with the conventional wordline underdrive (reference 400) is at a voltage level of Vwlud, where Vwlud<Vdd. Between the edges 250 and 252, the wordline signal with the pulsed wordline underdrive (reference 402) has a maximum voltage of Vdd−ΔV1 (the fixed underdrive voltage, where ΔV1<Vdd) that is greater than Vwlud, and includes a plurality of underdrive pulses 254 where, for each pulse, the voltage of the asserted wordline signal falls to a voltage of Vdd−ΔV2 (where ΔV2<Vdd; and ΔV1+ΔV2<Vdd) that is lower than Vwlud.

The bottom part of FIG. 8 shows the bitline voltages in response to the assertion of the wordline signal with the conventional wordline underdrive (reference 400) and the assertion of the wordline signal with the pulsed wordline underdrive (reference 402). In particular, it will be noted that there is an increased difference (Vdiff) between the true bitline (BLT) voltage 410 and the complement bitline (BLB) voltage 412 with use of the pulsed wordline underdrive (reference 402) compared to the conventional wordline underdrive (reference 400).

The use of the pulsed wordline underdrive (reference 402) provides a benefit during write operations. The lower wordline underdrive requirement or better wordline voltage level provides for improved write windows 420 (between consecutive pulses 254) compared to the conventional wordline underdrive (reference 400).

The foregoing description has provided by way of exemplary and non-limiting examples a full and informative description of the exemplary embodiment of this invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention as defined in the appended claims.

What is claimed is:

1. A method, comprising:
decoding an address to select a wordline coupled to a memory cell;
asserting a wordline signal on the selected wordline to perform a read/write operation at the memory cell, the asserted wordline signal having a leading edge and a trailing edge; and
between the leading edge and trailing edge, applying a plurality of wordline underdrive pulses to the asserted wordline signal, each wordline underdrive pulse causing a voltage of the asserted wordline signal to fall from a first voltage level to a second voltage level and then rise from the second voltage level to the first voltage level;
wherein the first and second voltage levels are both greater than a ground voltage of the memory cell.

2. The method of claim 1, wherein the first voltage level is equal to a supply voltage of the memory cell.

3. The method of claim 2, further comprising selecting a magnitude of a difference between the second voltage level and the first voltage level.

4. The method of claim 1, wherein the first voltage level is less than a supply voltage of the memory cell.

5. The method of claim 4, further comprising:
selecting a magnitude of a difference between the supply voltage and the first voltage level; and
selecting a magnitude of a difference between the second voltage level and the first voltage level

6. The method of claim 1, wherein there is an interval between successive wordline underdrive pulses of said plurality of wordline underdrive pulses, the method further comprising selecting the interval.

7. The method of claim 1, wherein each wordline underdrive pulse of said plurality of wordline underdrive pulses has a duration, the method further comprising selecting the duration.

8. A method, comprising:
selecting a wordline coupled to a memory cell; and
making a single assertion of a wordline signal on the selected wordline in connection with the performance of a read/write operation at the memory cell, wherein the single assertion has a leading edge and a trailing edge and, between the leading edge and trailing edge, the single assertion further includes a plurality of wordline underdrive pulses wherein each wordline underdrive pulse causes a wordline voltage to fall from a first voltage level to a second voltage level and then rise from the second voltage level to the first voltage level;
wherein the first and second voltage levels are both greater than a ground voltage of the memory cell.

9. The method of claim 8, wherein the first voltage level is equal to a supply voltage of the memory cell, and further comprising selecting the second voltage level.

10. The method of claim 8, wherein the first voltage level is less than a supply voltage of the memory cell, and further comprising selecting the first and second voltage levels.

11. The method of claim 8, wherein there is an interval between successive wordline underdrive pulses of said plurality of wordline underdrive pulses, the method further comprising selecting the interval.

12. The method of claim 8, wherein each wordline underdrive pulse of said plurality of wordline underdrive pulses has a duration, the method further comprising selecting the duration.

13. A circuit, comprising:
a wordline configured to be coupled to a memory cell powered by a supply voltage;
a pull-up transistor having a source-drain path connected between the supply voltage and the wordline wherein the pull-up transistor is actuated in response to selection of the wordline to perform a read/write operation at the memory cell;
a pull-down transistor having a source-drain path connected between the wordline and a ground node; and
a control circuit configured to apply a control signal to a control terminal of the pull-down transistor to provide wordline underdrive which includes a plurality of wordline underdrive pulses;
wherein each wordline underdrive pulse causes a wordline voltage to fall from a first voltage level to a second voltage level and then rise from the second voltage level to the first voltage level; and
wherein the first and second voltage levels are both greater than a ground voltage of the memory cell.

14. The circuit of claim 13, wherein the control circuit comprises:
a bias circuit coupled to a control terminal of the pull-down transistor and configured to set an amount of a fixed wordline underdrive; and
a pulse circuit coupled to the control terminal of the pull-down transistor and configured to apply the plurality of wordline underdrive pulses.

15. The circuit of claim 13, wherein the first voltage level is equal to the supply voltage of the memory cell.

16. The circuit of claim 13, wherein the first voltage level is less than a supply voltage of the memory cell.
